(19) United States
(12) Patent Application Publication
(10) Pub. No.: US 2017/0278886 A1
(43) Pub. Date: Sep. 28, 2017

(54) OPTICAL DEVICE AND PRODUCTION METHOD FOR OPTICAL DEVICE

(71) Applicant: FUJIKURA LTD., Tokyo (JP)

(72) Inventor: Daisuke AWAJI, Sakura-shi (JP)

(73) Assignee: Fujikura Ltd., Tokyo (JP)

(21) Appl. No.: 15/509,158

(22) PCT Filed: Apr. 4, 2016
(86) PCT No.: PCT/JP2016/061013

§ 371 Date: Mar. 6, 2017

(30) Foreign Application Priority Data
Jun. 19, 2015 (JP) 2015-124187

(51) Int. Cl. H01L 27/146; G02F 1/29

(52) U.S. Cl. CPC H01L 27/14625; H01L 27/14618; H01L 27/14685; G02F 1/29; G02F 2203/12

(57) ABSTRACT

A cover (8) of an optical device (10) is divided into: a first cover (5) which is fixed to a side wall section (4) so that an optical window (52) covers a light receiving section (1a) that serves as an effective region of an LCOS element (1); and a second cover (6) which is fixed to the side wall section (4) and the first cover (5) so as to cover an electrode terminal (3) and a wire (7) that connects the electrode terminal (3) and the semiconductor element (1b) to each other.

### TECHNICAL FIELD

The present invention relates to an optical device in which an optical element is sealed, and a method for producing the optical device.

### BACKGROUND ART

Conventionally, there is known an optical device which is arranged, in order to suppress an influence of humidity on an optical element, such that the optical element is provided inside a housing and a cover is provided so as to seal the optical element hermetically. There is also an optical device which is obtained by arranging the optical device above such that the cover has an opening which is covered with an optical window made of an optically transparent material so that the opening serves as a light path (for example, see Patent Literature 1).

FIG. 4 is a view schematically illustrating an arrangement of a conventional optical device 100 in which an optical element 11 is sealed. (a) of FIG. 4 is a cross-sectional view showing a state in which a cover is open, and (b) of FIG. 4 is a perspective view. The optical device 100 includes (i) the optical element 11 having a light receiving section 1a and a semiconductor element 11b, (ii) a substrate 20, a side wall section 40, and (iv) a cover 50. The substrate 20 is provided with an electrode terminal 30 thereon, and the electrode terminal 30 is wire-bonded to the semiconductor element 11b via a wire 70. The cover 50 includes a frame section 60 which has an opening 61 and is made of an optically nontransparent material, and an optical window 62 which covers the opening 61 and is made of an optically transparent material. Light enters the light receiving section 11a of the optical element 11 through the optical window 62. Thus in the optical element 11, the light receiving section 11a serves as an effective region that has an optical function. Note that although the description above states that light enters the light receiving section 11a, the light receiving section 11a may be a member which receives light, a member which emits light, or a member which can both receive and emit light. The optical window 62 serves as a light path for light that enters the light receiving section 11a or light that is emitted from the light receiving section 11a.

The optical device 100 is arranged such that the optical element 11 is disposed on the substrate 20 on which the side wall section 40 has been provided, and then the cover 50 is attached to the side wall section 40 so as to achieve hermetic sealing,.

### CITATION LIST

### Patent Literature

Patent Literature

Japanese Patent Application Publication, Tokukaihei, No. 9-148469 A (Publication Date: Jun. 6, 1997)

### SUMMARY OF INVENTION

### Technical Problem

According to the optical device 100, it is not possible to process an inside of the optical device 100 after hermetical sealing is done. Accordingly, it is necessary to process the inside before the cover 50 is attached to the side wall section 40. In doing so, each step is performed in a state where a foreign matter can easily adhere or accumulate on the optical element 11, since the optical element 11 is exposed. Examples of the foreign matter include a foreign matter that enters from outside, and a wire debris that is produced during a wire bonding step. In the wire bonding step, a bonding device is operated while the optical element 11 remains exposed. This significantly increases a possibility foreign matter adheres to the optical element. 11.

In a case where a foreign matter adheres to the light receiving section 11a of the optical element 11 as shown in FIG. 4, an amount and direction of light entering the light receiving section 11a or light emitted from the light receiving section 11a is changed by the foreign matter. This prevents the optical element 11 from accurately functioning. For example, in a case where the optical element 11 is a spatial light modulating element having a function of controlling an angle of reflected light, incident light is refracted by the foreign matter, so that crosstalk occurs which results in malfunction (abnormal output). Further, in a case where the optical element 11 is a solid-state image pickup device, refraction of light caused by the foreign matter results in a significant decrease in amount of light received.

The present invention is accomplished in view of the foregoing problem. An object of the present invention is to provide (i) an optical device which enables protection of an a effective region of an optical element from a foreign matter and accordingly enables suppression of deterioration in performance of the optical element caused by the foreign matter and (ii) a method for producing the optical device,

### Solution to Problem

In order to attain the object, an optical device in accordance with the present invention is an optical device including: an optical element; a substrate on which the optical element is mounted and an electrode terminal is provided; a side wall section surrounding the optical element and the electrode terminal; and a cover fixed to the side wall section and facing the substrate, the cover being divided into: a first cover including an optical window and fixed to the side wall section so that the optical window covers an effective region of the optical element; and a second cover fixed to the side wall section and the first cover so as to cover (i) a connecting member which connects the electrode terminal and the optical element to each other and (ii) the electrode terminal.

### Advantageous Effects of Invention

According to the present invention, it is possible to provide an optical device which enables protection of an effective region of an optical element from a foreign matter and accordingly enables suppression of deterioration in performance of the optical element caused by the foreign matter.

### BRIEF DESCRIPTION OF DRAWINGS

(a) of FIG. 1 is a cross-sectional view schematically illustrating an arrangement of an optical device of Embodiment 1 of the present invention, and (b) and (c) of FIG. 1 are a top view and a perspective view, respectively, of the optical device.

FIG. 2 is a cross-sectional view schematically illustrating an arrangement of an optical device of Embodiment 2 of the present invention.

FIG. 3 is a cross-sectional view schematically illustrating an arrangement of an optical device of Embodiment 3 of the present invention.

(a) of FIG. 4 is a cross-sectional view schematically illustrating an arrangement of a conventional optical device, and (b) of FIG. 4 is a perspective view of the optical device.

### DESCRIPTION OF EMBODIMENTS

### Embodiment 1

The following description will discuss an embodiment of the present invention, with reference to a drawing. In Embodiment 1 below, an optical device 10 which includes an LCOS (Liquid Crystal on Silicon) element 1 as an optical element ill be discussed.

(Arrangement of Optical Device)

FIG. 1 is a view schematically illustrating an arrangement of the optical device 10 of Embodiment 1. (a), (b), and (c) of FIG. 1 are a cross-sectional view, a top view, and a perspective view, respectively. Note that (a) of FIG. 1 shows the optical device 10 in a state where a second cover 6 (described below) is removed (a state before the second cover 6 is fixed).

As illustrated in FIG. 1, the optical device 10 includes the LCOS element 1, a substrate 2, a side wall section 4, and a cover 8.

The LCOS element is a spatial light modulating element having a function of controlling an angle of reflected light, and includes a semiconductor element 1b and a light receiving section 1a. The semiconductor element 1b includes a silicon substrate and a driving circuit which is for driving a light receiving section 1a and provided on the silicon substrate. The semiconductor element 1b has a mirror-like interface with the light receiving section 1a. The light receiving section 1a includes a liquid crystal layer and a glass layer, which are stacked in this order on the semiconductor element 1b. In accordance with a change in voltage applied to the liquid crystal layer, the LCOS element 1 changes liquid crystal alignment so as to change a reflection angle at which light entering the light receiving section 1a is reflected. That is, it is possible to control the reflection angle by controlling the voltage. In the LCOS element 1 thus arranged, the light receiving section 1a serves as an effective region having an optical function.

The substrate 2 is a member for having the LCOS element 1 mounted thereon, and is made of, for example, ceramic, metal, or the like. On the substrate 2, an electrode terminal 3 for electrical conduction with an outside of the optical device 10 is provided. The electrode terminal 3 and the semiconductor element 1b of the LCOS element 1 are connected to each other by wire bonding via a wire 7. The wire 7 is made of, for example, gold, aluminum or the like.

The side wall section 4 is a frame-like member which is provided on the substrate 2 so as to surround the LCOS element 1, and is made of, for example, ceramic, metal, or the like. Note that the side wall section 4 may be constituted by a plurality of members which are arranged in a shape of a frame. The side wall section 4 may be formed integrally with the substrate 2, or provided separately from the substrate 2. In a case where the wall section 4 is provided separately from the substrate 2, the side wall section 4 is, for example, fixed to the substrate 2 via a resin.

Further, a heater substrate may be provided between the substrate 2 and the LCOS element 1. In a case where the LCOS element 1 is heated by the heater substrate to a temperature higher than a normal temperature when the LCOS element 1 is used, it is possible to increase a speed of liquid crystal alignment as compared with a case in which the LCOS element 1 is used at a normal temperature. In a case where the heater substrate is provided, electric conduction to the heater substrate can also be realized via the electrode terminal 3 by wire bonding.

The cover 8 is a member which is fixed to the side wall section 4 so as to cover the substrate 2. That is, the optical device 10 is a device including a housing (package), which is constituted by the substrate 2, the side wall section 4, and the cover 8, and the LCOS element 1 which is sealed inside the housing. The cover 8 is divided into a first cover 5 and the second cover 6.

The first cover 5 includes a frame section 51a having an opening 53 formed therein, and an optical window 52. The frame section 51 is made of an optically nontransparent metal material. The opening 53 is covered by the optical window 52 which is made of an optically transparent material e.g., a glass substrate). The optical window 52 of the first cover 5 is provided above the light receiving section 1a, and the first cover 5 is fixed to the side wall section 4. Accordingly, incident light from outside the optical device 10 passes through the optical window 52 so as to be guided to the light receiving section 1a of the LCOS element Reflected light from the light receiving section 1a of the LCOS element 1 is emitted outside the optical device 10 through the optical window 52.

The second cover 6 is made of an optically nontransparent metal material, located so as to cover the electrode terminal 3 and the wire 7, and fixed to the side wall section 4.

Since the cover 8 is thus divided into the first cover 5 and the second cover 6, attachment of the cover 8 to the side wall section 4 can be carried out in two stages. As such, during a period from when the first cover 5 is attached to the side wall section 4 to when the second cover 6 is attached to the side wall section 4, the electrode terminal 3 and the semiconductor element 1b can he wire-bonded to each other in a state where the light receiving section 1a of the LCOS element 1 is protected by the first cover 5 covering the light receiving section 1a. Thereafter, the second cover 6 is attached to the side wall section 4 so that the LCOS element 1 is successfully sealed.

It is therefore possible in the optical device 10 to protect the light receiving section 1a of the LCOS element 1 from a foreign matter, thereby enabling suppression of deterioration in performance of the optical element caused by the foreign matter.

Further, as illustrated in (a) and (c) of FIG. 1, the second cover 6 has a protrusion 61 that covers part of the first cover 5, and the second cover 6 is fixed to the first cover 5 so as to overlap with the first cover 5 at the protrusion 61. This overlapping of at least part of the first cover 5 and at least part of the second cover 6 allows the first cover 5 and the second cover 6 to be firmly fixed to each other and, accordingly, allows the LCOS element 1 to be reliably sealed. Further, in a case of fixing the first cover 5 and the second cover 6 to each other by welding, the overlapping of at least part of the first cover 5 and at least part of the second cover 6 facilitates the welding as compared with a case where only an end surface of the first cover 5 and an end surface of the second cover 6 are caused to face each other and fixed to each other.

(Method for Producing Optical Device)

The following description will discuss a method for producing the optical device 10 of Embodiment 1.

First, on the substrate 2 on which the side wall section 4 has been attached (or on the substrate 2 which includes the side wall section 4), the LCOS element 1 is mounted.

Next, the first cover 5 is fixed to the side wall section 4 so that the optical window 52 of the first cover 5 covers the light receiving section 1a of the LCOS element 1 (first cover attaching step). Then, the semiconductor element 1b and the electrode terminal 3 are wire-bonded to each other via the wire 7 (connecting step). At this time, the wire bonding can he performed in a state where the first cover 5 protects the light receiving section 1a from a foreign matter.

Subsequently, the second cover 6 is fixed to the side wall section 4 and the first cover 5 so as to cover the electrode terminal 3 and the wire 7 (second cover attaching step). In this manner, the optical device 10 in which the LCOS element I is sealed can be produced.

In Embodiment 1, the fixation of the first cover 5 and the fixation of the second cover 6 are each done by seam welding. However, in a case where the optical device 10 includes an optical element that does not need to be hermetically sealed, the fixations may be done by resin bonding.

A production method other than the above-described method can he performed with use of a conventionally well-known technique, and descriptions on such a method are therefore omitted.

### Embodiment 2

The following description will discuss another embodiment of the present invention, with reference to a drawing. In Embodiment 2 below, an optical device 10A which includes an LCOS element 1 will be discussed.

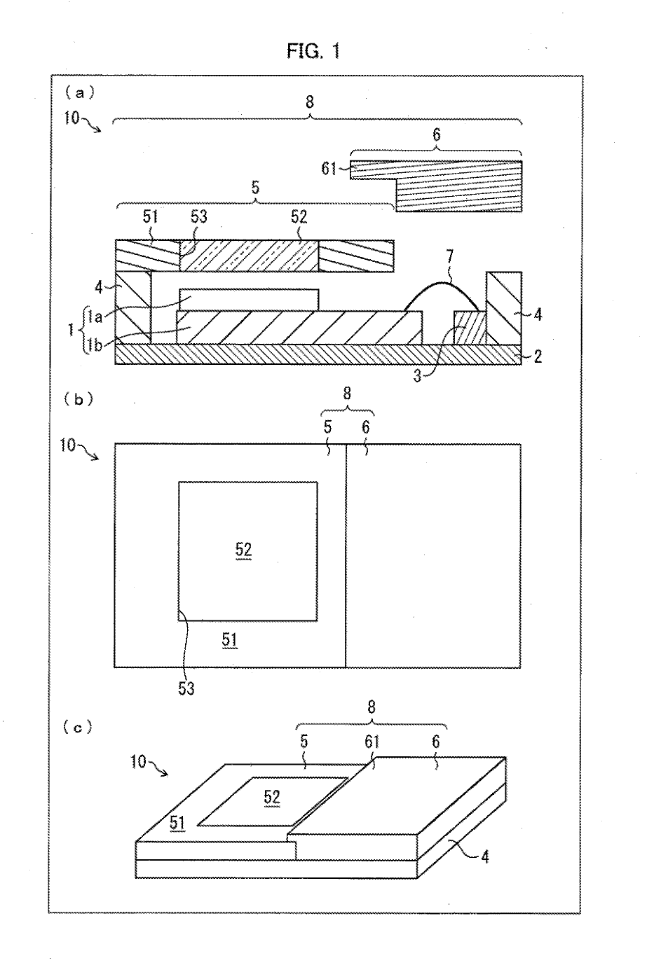

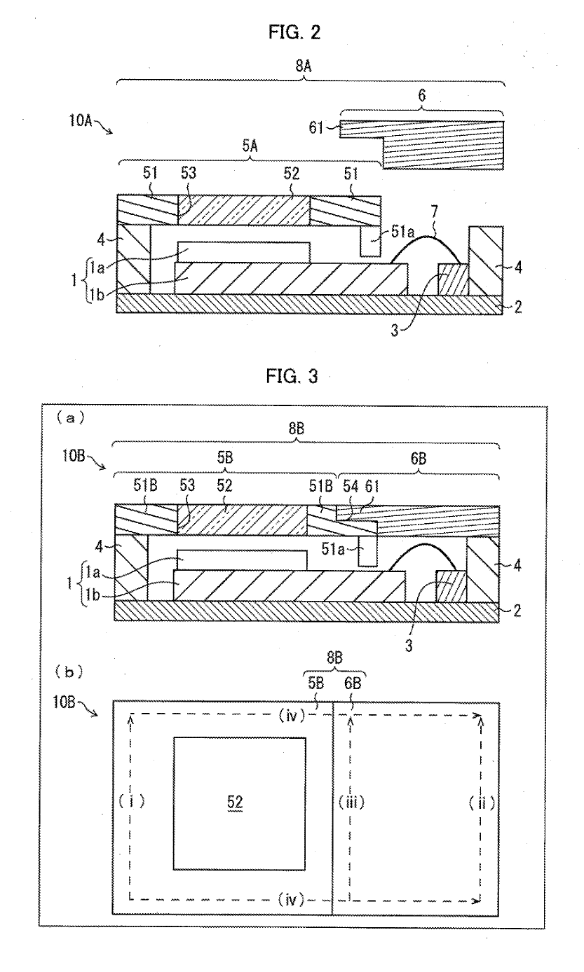

FIG. 2 is a cross-sectional view schematically illustrating the optical device 10A of Embodiment 2.

The optical device 10A illustrated in FIG. 2 differs from the optical device 10 in that the optical device 10A includes a cover 8A instead of the cover 8. Other arrangements of the optical device 10A are similar to those of the optical device 10. As such, the same reference sign will be given to identical members, and descriptions on such members will be omitted.

The cover 8A has a first cover 5A and a second cover 6. The second cover 6 is identical to the second cover 6 included in the cover 8 of the optical device 10. FIG. 2 shows the optical device 10A in a state where the second cover is removed. A top view and a perspective view of the optical device 10A in a state where the second cover 6 is closed are similar to (b) and (c) of FIG. 1, respectively.

As illustrated in FIG. 2, the first cover 5A includes a partition section 51a in addition to the arrangement of the first cover 5. The partition section 51a is a partition which is provided in order to separate a light receiving section 1a from an electrode terminal 3 and a wire 7, and has a shape protruding from a frame section 51 toward a substrate 2.

In Embodiment 2, the partition section 51a is made of a material different from that of the frame section 5l, and is fixed to the frame section 51. Since the partition section 51a is provided separately from the frame section 51, a material that does not affect the LCOS element 1, the substrate 2, and the like can be selected as a material of the partition section 51a. The partition section 51a is made of, for example, resin, and is fixed to the frame section 51 at a position where the partition section 51a allows the light receiving section 1a to be separated from the electrode terminal 3 and the wire 7. Note that the partition section 51a may be formed integrally with the frame section 51.

The partition section 51a allows the light receiving section 1a to be separated from the electrode terminal 3 and the wire. Even if debris of the wire 7 is generated from wire bonding performed during a period from when the first cover 5A is attached to When the second cover 6 is attached, the partition section 51a allows suppressing migration of the debris from a region where the electrode terminal 3 and the wire 7 are provided to a region where the light receiving section 1a is provided.

### Embodiment 3

The following description will discuss yet another embodiment of the present invention, with reference to a drawing. In Embodiment 3 below, an optical device 10B which includes an LCOS element 1 will be discussed.

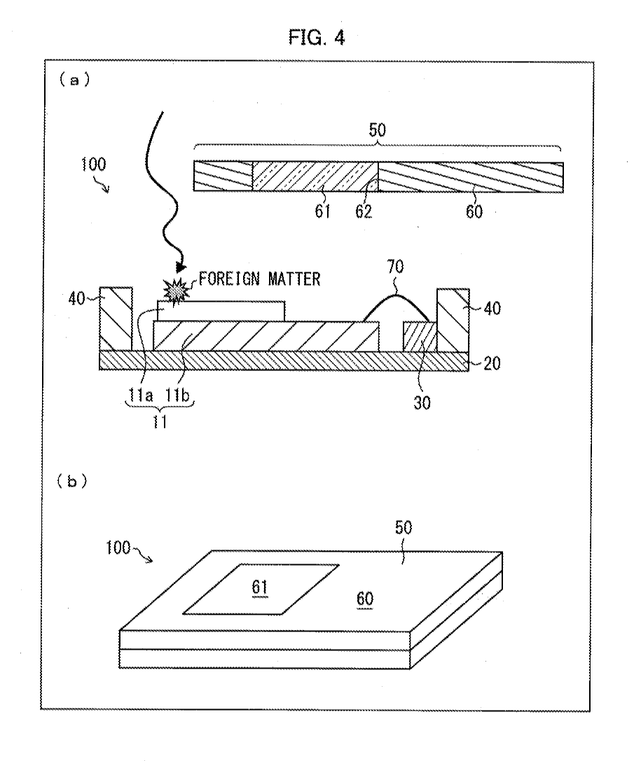

FIG. 3 is a view schematically illustrating an arrangement of the optical device 10B of Embodiment 3. (a) and (b) of FIG. 3 are a cross-sectional view and a top view, respectively.

As shown in (a) of FIG. 3, the optical device 10B differs from the optical device 10 in that the optical device 10B includes a cover 8B instead of the cover 8. Other arrangements of the optical device 10B are similar to those of the optical device 10. As such, the same reference sign will he given to identical members, and descriptions on such members will be omitted.

The cover 8B includes a first cover 5B, which includes a frame section 51B and an optical window 52, and a second cover 6B. An upper surface of the first cover 5B and an upper surface of the second cover 6B are continuous with each other so as to form a flat surface together.

The frame section 51B of the first cover 5B differs from the frame section 51 of the first cover 5 in that the frame section 51B has a recess 54 which is provided in a region where the first cover 5B and the second cover 6B are connected to each other and into which a protrusion 61 of the second cover 6B is fitted. The second cover 6B differs from the second cover 6 in that the protrusion 61 has a shape that fits into the recess 54 of the first cover 5B and that after the protrusion 61 is embedded in the recess 54, the upper surface of the second cover 6B and the upper surface of the first cover 5B are continuous with each other so as to form a flat surface together.

Further, in Embodiment 3, the first cover 5B includes a partition section 51a as with the first cover described in Embodiment 2. Note, however, that the first cover 5B does not have to include the partition section 51a.

In the optical device 10B, since the upper surface of the first cover 5B and the upper surface of the second cover 6B are continuous with each other so as to form a flat surface together, the first cover 5B and the second cover 6B can be fixed to a side wall section 4 in the same motion in a case where seam welding is carried out. This will be detailed below.

First, as indicated by a dotted arrow (i) in (b) of FIG. 3, the first cover 5B is seam-welded with a portion of the side wall section 4 which portion is touched only by the first cover 5B. The dotted arrow indicates a direction in which the seam welding is performed, but the seam welding may be performed in an opposite direction, as a matter of course. Subsequently, the semiconductor element 1b and the electrode terminal 3 are wire-bonded with each other, and the second cover 6B is arranged. Then, as indicated by a dotted arrow (ii) in (b) of FIG. 3, the second cover 6B is seam-welded to a portion of the side wall section 4 which portion is touched only by the second cover 6B. Subsequently, as indicated by a dotted arrow (iii) in (b) of FIG. 3, the first cover 5B and the second cover 6B are seam-welded to each other and as indicated dotted arrows (iv) in (b) of FIG. 3 the first cover 5B and the second cover 6B are seam-welded to the side wall section 4 in the same motion. Note that an order in which the seam weldings indicated by the respective dotted arrows (ii) through (iv) are performed is not limited to the above order. For example, the seam weld rigs may be performed in an order of (iv), (iii), and then (ii).

Each of Embodiments 1 through 3 has described an optical device which includes an LCOS element as an optical element. Note, however, that an optical element included in an optical device in accordance with the present invention is not limited to this. That is, the optical element included in the optical device in accordance with the present invention can be any element that is stored in a housing, and can be, for example, an MEMS (Micro Electro Mechanical System) mirror element. Further, the optical element can be a solid-state image pickup device. In this case, the arrangement of the optical device in accordance with the present invention brings about an advantageous effect that a decrease in amount of light received by the optical element (solid-state image pickup device) is suppressed.

[Conclusion]

An optical device in accordance with the present embodiment is an optical device including: an optical element; a substrate on which the optical element is mounted and in electrode terminal is provided; a side wall section surrounding the optical element and the electrode terminal; and a cover fixed to the side wall section and facing the substrate, the cover being divided into: a first cover including an optical window and fixed to the side wall section so that the optical window covers an effective region of the optical element; and a second cover fixed to the side wall section and the first cover so as to cover (i) a connecting member which connects the electrode terminal and the optical element to each other and (ii) the electrode terminal.

According to the arrangement above, since the cover is divided into the first cover and the second cover, attachment of the cover to the side wall section can he carried out in two stages. As such, during a period from when the first cover is attached to the side wall section to when the second cover is attached to the side wall section, the electrode terminal and the optical element can be connected to each other via the connecting member in a state where the effective region of the optical element is protected by the first cover covering the effective region. Thereafter, the second cover is attached to the side wall section, so that the optical element is successfully sealed.

As is clear from the above description, the arrangement above allows protecting the effective region of the optical element from a foreign matter, thereby enabling suppression of deterioration in performance of the optical element caused by the foreign matter. Accordingly, it becomes possible to provide a highly reliable optical device.

Further, the optical device in accordance with the present embodiment is preferably further arranged such that the first cover includes a partition section protruding toward the substrate and separating the effective region from the electrode terminal and the connecting member.

According to the arrangement above, the partition section protruding toward the substrate allows the effective region of the optical element to be separated from the electrode terminal and the connecting member. Even if a debris of the connecting member is generated from connection of the connecting member to the electrode terminal which is performed during a period from when the first cover is attached to when the second cover is attached, the partition section allows suppressing migration of the debris from a region where the electrode terminal and the connecting member are provided to the effective region.

Note here that since the partition section protrudes toward the substrate, it is preferable that the partition section be provided separately from the part (frame section) of the first cover other than the optical window and attached to the frame section. In a case where the partition section is separately provided, a material that does not affect the optical element, the substrate, and the like can be selected as a material of the partition section, and furthermore, a greater degree of freedom is provided with regards to the shape of the partition section.

Further, the optical device in accordance with the present embodiment is preferably further arranged such that an upper surface of the first cover send an upper surface of the second cover are continuous with each other so as to form a flat surface together.

According to the arrangement above, since the upper surfaces are continuous with each other so as to form a flat surface together, the first cover and the second cover can be fixed to the side wall section in the same motion in a case where seam welding is carried out.

Further, the optical device in accordance with the present embodiment is preferably further arranged such that the first cover and the second cover are fixed to each other so that at least part of the first cover and at least part of the second cover overlap with each other.

According to the arrangement above, the overlapping of at least part of the first cover and at least part of the second cover allows the first cover and the second cover to be firmly fixed to each other and, accordingly, allows the optical element to be reliably sealed. Further, in a case of fixing the first cover and the second cover to each other by welding, the overlapping facilitates the welding as compared with a case where only an end surface of the first cover and an end surface of the second cover are caused to face each other and fixed to each other.

Further, a method, in accordance with the present embodiment, for producing an optical device is a method for producing an optical device which includes: an optical element; a substrate on which the optical element is mounted and an electrode terminal is provided; a side wall section surrounding the optical element and the electrode terminal; and a cover fixed to the side wall section and facing the substrate, said method including: a first cover attaching step of fixing a first cover, which is part of the cover and includes an optical window, to the side wall section so that the optical window covers an effective region of the optical element; a connecting step of connecting the optical element and the electrode terminal to each other via a connecting member; and a second cover attaching step of attaching a second cover, which is part of the cover other than the first cover, to the side wall section and the first cover so as to cover the electrode terminal and the connecting member.

According to the method, the optical element and the electrode terminal can be connected to each other via the connecting member in a state where the first cover is attached so as to protect the effective region of the optical element from a foreign matter. Thereafter, the second cover, which is part of the cover other than the first cover, is attached, so that an optical device in which the optical element is sealed is successfully produced. Thus, the method allows producing the optical device while the effective region of the optical element is protected from a foreign matter.

Note that the optical device in accordance with the present embodiment in which optical device the optical element has not been mounted, that is, a housing or package which includes the substrate, the side wall section, and the cover having the first cover and the second cover, is also encompassed in the scope of the present invention.

[Additional Matter]

The present invention is not limited to the embodiments, but can be altered by a skilled person in the art within the scope of the claims. An embodiment derived from a proper combination of technical means each disclosed in a different embodiment is also encompassed in the technical scope of the present invention.

### INDUSTRIAL APPLICABILITY

The present invention is applicable to an optical device in which an optical element is sealed, and a method for producing the optical device.

### REFERENCE SIGNS LIST

1 LCOS element (optical element)

1a Light receiving section (effective region)

1b Semiconductor element.

2 Substrate

Electrode terminal

4 Side wall section

5, 5A, 5B First cover

6, 6A, 6B Second cover

7 Wire (connecting member)

8, 8A, 8B Lid section

10, 10A, 108 Optical device

52 Optical window

54 Recess

61 Protrusion

100 Conventional optical device

1. An optical device comprising:
an optical element;
a substrate on which the optical element is mounted and an electrode terminal is provided;
a side wall section surrounding the optical element and the electrode terminal; and
a cover fixed to the side wall section and facing the substrate,
the cover being divided into:
a first cover including an optical window and fixed to the side wall section so that the optical window covers an effective region of the optical element; and
a second cover fixed to the side wall section and the first cover so as to cover (i) a connecting member which connects the electrode terminal and the optical element to each other and (ii) the electrode terminal.

2. The optical device as set forth in claim 1, wherein the first cover includes a partition section protruding toward the substrate and separating the effective region from the electrode terminal and the connecting member.

3. The optical device as set forth in claim 1, wherein an upper surface of the first cover and an upper surface of the second cover are continuous with each other so as to form a flat surface together.

4. The optical device as set forth in claim 1, wherein the first cover and the second cover are fixed to each other so that at least part of the first cover and at least part of the second cover overlap with each other.

5. A method for producing an optical device,
said optical device including:
an optical element;
a substrate on which the optical element is mounted and an electrode terminal is provided;
a side wall section surrounding the optical element and the electrode terminal; and
a cover fixed to the side wall section and facing the substrate,
said method comprising:
a first cover attaching step of fixing a first cover, which is part of the cover and includes an optical window, to the side wall section so that the optical window covers an effective region of the optical element;
a connecting step of connecting the optical element and the electrode terminal to each other via a connecting member; and
a second cover attaching step of attaching a second cover, which is part of the cover other than the first cover, to the side wall section and the first cover so as to cover the electrode terminal and the connecting member.
